(19) United States
(12) Patent Application Publication
(10) Pub. No.: US 2012/0152346 A1
(43) Pub. Date: Jun. 21, 2012

(54) LIGHT ABSORPTION-ENHANCING SUBSTRATE STACKS

(75) Inventors: Fan Yang, Sunnyvale, CA (US); Sijin Han, Milpitas, CA (US)

(73) Assignee: QUALCOMM MEMS Technologies, Inc., San Diego, CA (US)

(21) Appl. No.: 12/973,717

(22) Filed: Dec. 20, 2010

(51) Int. Cl. H01L 31/0216; B05D 5/12

(52) U.S. Cl. 136/256; 427/74

(57) ABSTRACT

This disclosure provides substrate stacks for use in photovoltaic cells and methods of manufacturing the same. In one aspect, a substrate stack can include a substrate layer having at least one surface with an RMS roughness value that is greater than 9 nm. The substrate stack can also include a transparent conductive oxide layer disposed over the substrate layer. The transparent conductive oxide layer can include at least a first surface with an RMS roughness value that is greater than 9 nm and a second surface with an RMS roughness value that is greater than 9 nm. The RMS roughness value of the second surface can be greater than the RMS value of the first surface.

### TECHNICAL FIELD

This disclosure relates generally to the field of optoelectronic transducers that convert optical energy into electrical energy, for example, photovoltaic cells.

### DESCRIPTION OF THE RELATED TECHNOLOGY

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the availability of fossil fuel. In addition, geopolitical issues can quickly affect the supply of such fuel. Global warming is also of greater concern in recent years. A number of factors are thought to contribute to global warming; however, widespread use of fossil fuels is presumed to be a main cause of global warming. Thus there is an urgent need to find a renewable and economically viable source of energy that is also environmentally safe. Solar energy is an environmentally friendly renewable source of energy that can be converted into other forms of energy such as heat and electricity.

Photovoltaic cells convert optical energy to electrical energy and thus can be used to convert solar energy into electrical power. Photovoltaic solar cells can be made very thin and modular. Photovoltaic cells can range in size from a about few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Photovoltaic cells can be used in a wide range of applications such as providing power to satellites and other spacecraft, providing electricity to residential and commercial properties, charging automobile batteries, etc.

While photovoltaic devices have the potential to reduce reliance upon fossil fuels, the widespread use of photovoltaic devices has been hindered by inefficiency concerns and concerns regarding the material costs required to produce such devices. Accordingly, improvements in efficiency and/or manufacturing costs could increase usage of photovoltaic devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in a substrate stack for use in a photovoltaic cell. The substrate stack can include a substrate layer having a front surface and a rear surface disposed opposite to the front surface. An unevenness of the rear surface can be characterized by an RMS roughness value that is greater than 9 nanometers. The substrate stack can also include a first transparent conductive oxide layer disposed over the rear surface of the substrate layer. The first transparent conductive oxide layer can have a first surface disposed adjacent to the rear surface of the substrate layer and a second surface disposed opposite to the first surface. An unevenness of the first surface can be characterized by an RMS roughness value of greater than 9 nanometers and an unevenness of the second surface can be characterized by an RMS roughness value of greater than 9 nanometers. In one aspect, the RMS roughness value of the unevenness of the first surface of the first transparent conductive oxide layer can be between 10 nm and 200 nm. In another aspect, the RMS roughness value of the unevenness of the first surface of the first transparent conductive oxide layer can be about the same as the RMS roughness value of the unevenness of the rear surface of the substrate layer.

Another innovative aspect of the subject matter described in this disclosure can be implemented in a substrate stack for use in a photovoltaic cell. The substrate stack can include a substrate layer have a front surface and a rear surface disposed opposite to the front surface and a first transparent conductive oxide layer. The first transparent conductive oxide layer can be disposed over the rear surface of the substrate layer and can include a first surface and a second surface. The first surface can be disposed between the second surface and the rear surface of the substrate layer and can have an unevenness characterized by an RMS roughness value of greater than 9 nanometers. The second surface can have an unevenness characterized by an RMS roughness value that is greater than the RMS roughness value of the unevenness of the first surface. In one aspect, an unevenness of the rear surface of the substrate layer can be characterized by an RMS roughness value that is greater than 19 nm and/or an unevenness of the second surface of the first transparent conductive oxide layer can be characterized by an RMS value of between 20 and 1000 nm.

Another innovative aspect of the subject matter described in this disclosure can be implemented in a method of manufacturing a substrate stack for use in a photovoltaic cell. The method can include providing a substrate layer having a front surface and a rear surface disposed opposite to the front surface, increasing an unevenness of the rear surface such that an RMS roughness value of the rear surface is greater than 9 nanometers, and depositing a transparent conductive oxide layer on the rear surface such that the deposited transparent conductive oxide layer has a first surface that contacts the rear surface and a second surface disposed opposite to the first surface. An unevenness of the first surface can be characterized by an RMS roughness value of greater than 9 nanometers and an unevenness of the second surface can be characterized by an RMS roughness value of greater than 9 nanometers. In one aspect, the method can include increasing the unevenness of the second surface such that the RMS roughness value of the unevenness of the second surface is greater than the RMS roughness value of the first surface.

Yet another innovative aspect of the subject matter described in this disclosure can be implemented in a substrate stack for use in a photovoltaic cell. The substrate stack can include a substrate layer having a front surface and a rear surface disposed opposite to the front surface and means for conducting a current flow. The conductive means can be disposed over the rear surface of the substrate layer and can have a first surface and a second surface disposed opposite to the first surface. The first surface can be disposed between the second surface and the rear surface of the substrate layer and can have an unevenness characterized by an RMS roughness value of greater than 9 nanometers. An unevenness of the second surface can be characterized by an RMS roughness value that is greater than the RMS roughness value of the first surface. In one aspect, the RMS roughness value of the unevenness of the second surface is between 20 and 1000 nm.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A is an example of a cross-section of one implementation of a photovoltaic cell including a p-n junction.

FIG. 1B is an example of a block diagram that schematically illustrates a cross-section of one example of a photovoltaic cell including a deposited thin film photovoltaic active material.

FIG. 2A is an example of a cross-section of one implementation of a photovoltaic cell including a roughened surface interface between a photovoltaic active layer and a transparent conductive oxide layer.

FIGS. 2B and 2C are examples of cross-sections of two implementations of photovoltaic cells including a first roughened surface interface between a photovoltaic active layer and a transparent conductive oxide layer and a second roughened surface interface between the transparent conductive oxide layer and a substrate layer.

FIG. 2D is an example of a cross-section of one implementation of a photovoltaic cell including a first roughened surface interface between a photovoltaic active layer and a transparent conductive oxide layer, a second roughened surface interface between the transparent conductive oxide layer and a substrate layer, and a third roughened surface interface on a side of the substrate layer opposite to the second roughened surface interface.

FIG. 3A is an example of a cross-section of one implementation of a substrate layer used to manufacture a substrate stack.

FIG. 3B is an example of a cross-section of the substrate layer of FIG. 3A after one surface of the substrate layer has been roughened.

FIG. 3C is an example of a cross-section of the substrate layer of FIG. 3B shown with a transparent conductive oxide layer deposited on the roughened surface.

FIG. 3D is an example of a cross-section of the substrate layer and transparent conductive oxide layer of FIG. 3C after a surface of the transparent conductive oxide layer opposite the substrate layer has been roughened.

FIG. 4 is an example of a block diagram schematically illustrating one implementation of a method of manufacturing a substrate stack for use in a photovoltaic cell.

FIG. 5A is an example of a chart that relates the light scattering to the surface roughness of a light surface interface.

FIG. 5B is an example of a chart that relates the thickness requirement for a photovoltaic active layer to the surface roughness of a front transparent conductive oxide layer of a photovoltaic cell.

Like reference numbers and designations in the various drawings indicate like elements.

### DETAILED DESCRIPTION

Two issues hindering widespread adoption of photovoltaic (PV) devices include inefficiency concerns and the material costs required to produce such devices. Implementations of photovoltaic devices disclosed herein may include multiple roughened surface interfaces through which incident light must pass before reaching a photovoltaic active material layer. These roughened surface interfaces scatter the light that passes therethrough such that the light absorbing path (e.g., the path of the light through the device) of the scattered light beams through the layers of the photovoltaic devices is increased. Increasing the light absorbing path through the photovoltaic active layer can increase the photocurrent that flows through the photovoltaic active layer and therefore increase the overall electrical power produced by the photovoltaic active layer. Thus, the efficiency of the photovoltaic devices (e.g., the amount of electrical power produced) can be increased and/or the thickness of the photovoltaic active layer can be decreased resulting in lower material costs. Reducing the thickness of the photovoltaic active layer can also help to reduce the device degradation (e.g., Steabler-Wronski effect in a-Si), thus increasing the stable performance lifetime of the photovoltaic device. Further, as discussed in more detail below, such implementations can reduce manufacturing processing costs and times. Moreover, the diffusive nature of the scattered incident light diminishes the dependence of the photovoltaic device efficiency on the location of the sun. For example, when sun light is incident on the photovoltaic device at an oblique angle relative to the photovoltaic device, one or more roughened surface interfaces may act to reduce the amount of light that is reflected away from the device. Reducing the angular dependence of incident light can expand the installation flexibility of photovoltaic devices and increases the overall power output.

Although certain implementations and examples are discussed herein, it is understood that the inventive subject matter extends beyond the specifically disclosed implementations to other alternative implementations and/or uses of the invention and obvious modifications and equivalents thereof. It is intended that the scope of the inventions disclosed herein should not be limited by the particular disclosed implementations. Thus, for example, in any method or process disclosed herein, the acts or operations making up the method/process may be performed in any suitable sequence and are not necessarily limited to any particular disclosed sequence. Various aspects and features of the implementations have been described where appropriate. It is to be understood that not necessarily all such aspects or features may be achieved in accordance with any particular implementation. Thus, for example, it should be recognized that the various implementations may be carried out in a manner that achieves or optimizes one feature or group of features as taught herein without necessarily achieving other aspects or features as may be taught or suggested herein. The following detailed description is directed to certain specific implementations of the invention. However, the invention can be implemented in a multitude of different ways. The implementations described herein may be implemented in a wide range of devices that incorporate photovoltaic devices for conversion of optical energy into electrical current.

In this description, reference is made to the drawings wherein like parts are designated with like numerals throughout. As will be apparent from the following description, the implementations may be implemented in a variety of devices that include photovoltaic active material.

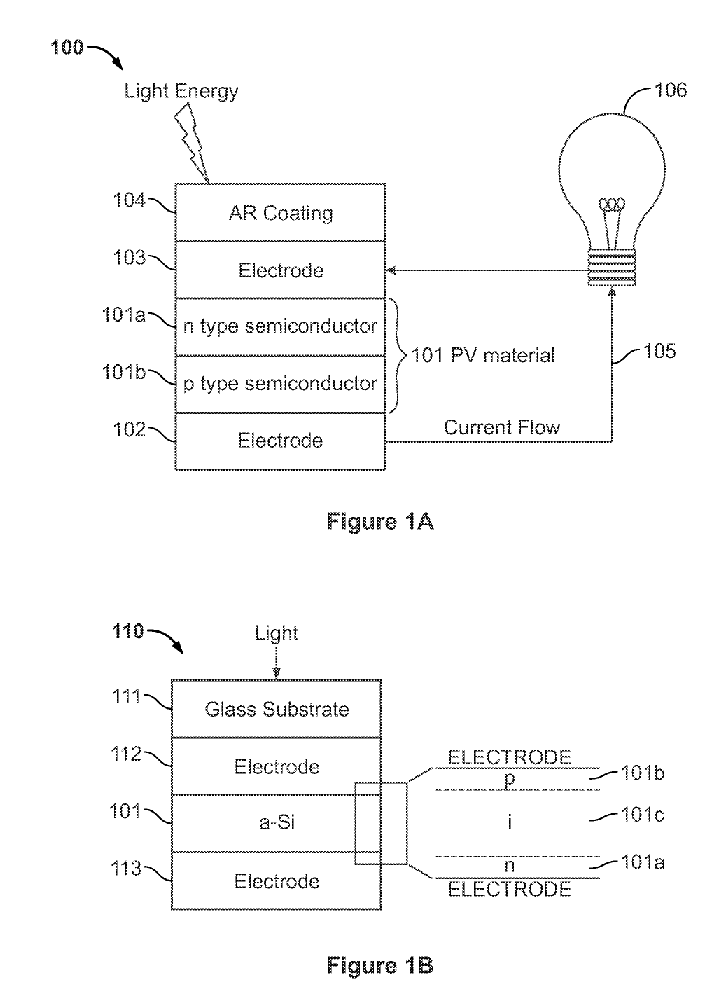

Turning now to the Figures, FIG. 1A is an example of a cross-section of one implementation of a photovoltaic cell including a p-n junction. A photovoltaic cell can convert light energy into electrical energy or current. A photovoltaic cell is an example of a renewable source of energy that has a small carbon footprint and has less impact on the environment. Using photovoltaic cells can reduce the cost of energy generation. Photovoltaic cells can have many different sizes and shapes, e.g., from smaller than a postage stamp to several inches across. Several photovoltaic cells can often be connected together to form photovoltaic cell modules up to several feet long and several feet wide. Modules, in turn, can be combined and connected to form photovoltaic arrays of different sizes and power output.

The size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A photovoltaic device can be a single cell with its attendant electrical connections and peripherals, a photovoltaic module, a photovoltaic array, or solar panel. A photovoltaic device can also include functionally unrelated electrical components, e.g., components that are powered by the photovoltaic cell(s).

With reference to FIG. 1A, a photovoltaic cell 100 includes a photovoltaic active region 101 disposed between two electrodes 102, 103. In some implementations, the photovoltaic cell 100 includes a substrate on which a stack of layers is formed. The photovoltaic active layer 101 of a photovoltaic cell 100 may include a semiconductor material, for example, silicon. In some implementations, the active region may include a p-n junction formed by contacting an n-type semiconductor material 101a and a p-type semiconductor material 101b as shown in FIG. 1A. Such a p-n junction may have diode-like properties and may therefore be referred to as a photodiode structure as well.

The photovoltaic active material 101 is sandwiched between two electrodes that provide an electrical current path. The back electrode 102 can be formed of aluminum, silver, or molybdenum or some other conducting material. The front electrode 103 may be designed to cover a significant portion of the front surface of the p-n junction so as to lower contact resistance and increase collection efficiency. In implementations wherein the front electrode 103 is formed of an opaque material, the front electrode 103 may be configured to leave openings over the front of the photovoltaic active layer 101 to allow illumination to impinge on the photovoltaic active layer 101. In some implementations, the front and back electrodes 103, 102 can include a transparent conductor, for example, transparent conducting oxide (TCO), for example, aluminum-doped zinc oxide (ZnO:Al), fluorine-doped tin Oxide (SnO₂:F), or indium tin oxide (ITO). The TCO can provide electrical contact and conductivity and simultaneously be transparent to incident radiation, including light. As discussed in more detail below, in some implementations, the front electrode 103 disposed between the source of light energy and the photovoltaic active material 101 can include one or more roughened surface interfaces to scatter light beams that pass therethrough. The scattering of light can increase the light absorbing path of the scattered light beams through the photovoltaic active material 101 and thus increase the electrical power output of the cell 100. In some implementations, the photovoltaic cell 100 can also include an anti-reflective (AR) coating 104 disposed over the front electrode 103. The AR coating 104 can reduce the amount of light reflected from the front surface of the photovoltaic active material 101.

When the front surface of the photovoltaic active material 101 is illuminated, photons transfer energy to electrons in the active region. If the energy transferred by the photons is greater than the band-gap of the semiconducting material, the electrons may have sufficient energy to enter the conduction band. An internal electric field is created with the formation of the p-n junction or p-i-n junction. The internal electric field operates on the energized electrons to cause these electrons to move, thereby producing a current flow in an external circuit 105. The resulting current flow can be used to power various electrical devices, for example, a light bulb 106 as shown in FIG. 1A.

The photovoltaic active material layer(s) 101 can be formed by any of a variety of light absorbing, photovoltaic materials, for example, microcrystalline silicon (μc-silicon), amorphous silicon (a-silicon), cadmium telluride (CdTe), copper indium diselenide (CIS), copper indium gallium diselenide (CIGS), light absorbing dyes and polymers, polymers dispersed with light absorbing nanoparticles, III-V semiconductors, for example, GaAs, etc. Other materials may also be used. The light absorbing material(s) where photons are absorbed and transfer energy to electrical carriers (holes and electrons) is referred to herein as the photovoltaic active layer 101 or material of the photovoltaic cell 100, and this term is meant to encompass multiple active sub-layers. The material for the photovoltaic active layer 101 can be chosen depending on the desired performance and the application of the photovoltaic cell. In implementations where there are multiple active sublayers, one or more of the sublayers can include the same or different materials.

In some arrangements, the photovoltaic cell 100 can be formed by using thin film technology. For example, in one implementation, where optical energy passes through a transparent substrate, the photovoltaic cell 100 may be formed by depositing a first or front electrode layer 103 of TCO on a substrate. The substrate layer and the transparent conductive oxide layer 103 can form a substrate stack that may be provided by a manufacturer to an entity that subsequently deposits a photovoltaic active layer 101 thereon. After the photovoltaic active layer 101 has been deposited, a second electrode layer 102 can be deposited on the layer of photovoltaic active material 101. The layers may be deposited using deposition techniques including physical vapor deposition techniques, chemical vapor deposition techniques, for example, plasma-enhanced chemical vapor deposition, and/or electro-chemical vapor deposition techniques, etc. Thin film photovoltaic cells may include amorphous, monocrystalline, or polycrystalline materials, for example, thin-film silicon, CIS, CdTe or CIGS. Thin film photovoltaic cells facilitate small device footprint and scalability of the manufacturing process.

FIG. 1B is an example of a block diagram that schematically illustrates a cross-section of one example of a photovoltaic cell including a deposited thin film photovoltaic active material. The photovoltaic cell 110 includes a glass substrate layer 111 through which light can pass. Disposed on the glass substrate 111 are a first electrode layer 112, a photovoltaic active layer 101 (shown as including amorphous silicon), and a second electrode layer 113. The first electrode layers 112 can include a transparent conducting material, for example, ITO. As illustrated, the first electrode layer 112 and the second electrode layer 113 sandwich the thin film photovoltaic active layer 101 therebetween. The illustrated photovoltaic active layer 101 includes an amorphous silicon layer. As is known in the art, amorphous silicon serving as a photovoltaic material may include one or more diode junctions. Furthermore, an amorphous silicon photovoltaic layer or layers may include a p-i-n junction wherein a layer of intrinsic silicon 101c is sandwiched between a p-doped layer 101b and an n-doped layer 101a. A p-i-n junction may have higher efficiency than a p-n junction. In some other implementations, the photovoltaic cell 110 can include multiple junctions.

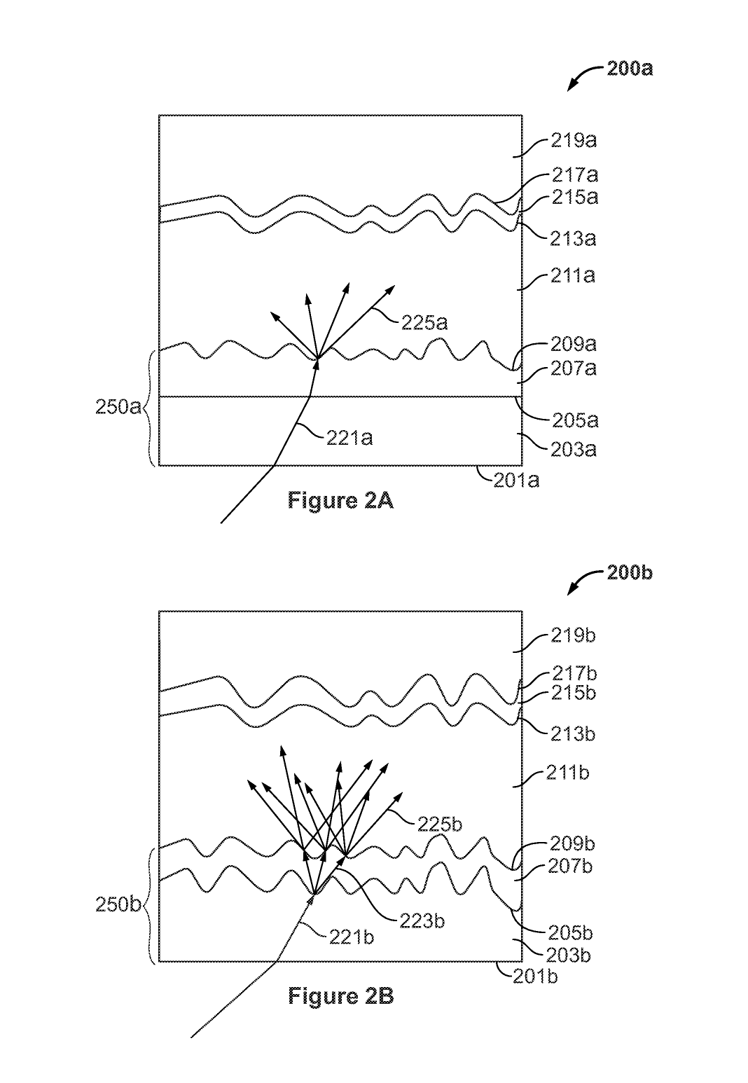

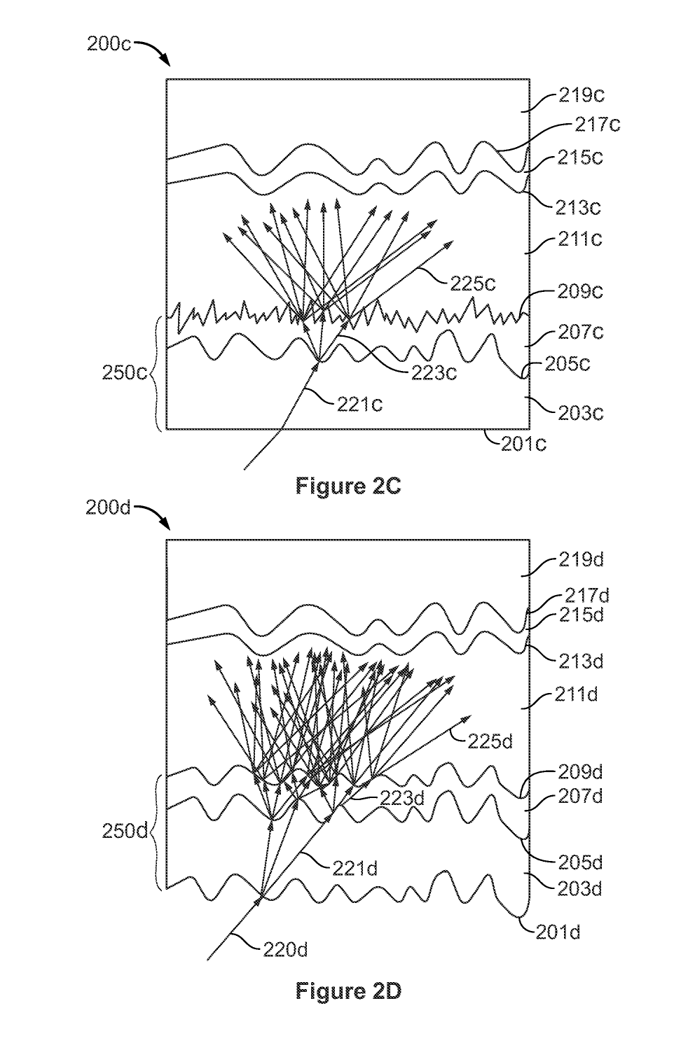

Turning now to FIGS. 2A-2D, implementations of photovoltaic cells including one or more roughened surface interfaces are schematically illustrated. As used herein, a surface interface refers to a surface or boundary of a layer of a photovoltaic device through which light passes. Surface interfaces can be disposed between separate layers of a photovoltaic cell and/or between a layer of a photovoltaic cell and the environment. The roughness of a surface or surface interface can be characterized by a surface roughness value which is a measure of a texture or unevenness of a surface or interface. A surface roughness value can be quantified by the vertical deviations of a real surface from its ideal form. If these deviations are large, the surface is rough and the surface roughness value is higher. If the deviations are small, the surface is smooth and the surface roughness value is lower. One method of characterizing the unevenness of a surface (e.g., characterizing the surface roughness value) is to perform a root mean squared (“RMS”) roughness value calculation for the given surface as defined by Equation 1 (below).

$$RMS = \sqrt{\frac{{h}_{1}^{2} + {h}_{2}^{2} + … + {h}_{n}^{2}}{n}} \qquad [ Equation 1 ]$$

As can be seen by Equation 1, the RMS roughness value for a given surface increases with the roughness or unevenness of the surface. Surface roughness can lead to the scattering of light beams that are incident on the rough surface. Light scattering, or diffuse reflection, results in the deflection of scattered rays (e.g., flare or stray light) in random directions.

FIG. 2A is an example of a cross-section of one implementation of a photovoltaic cell including a roughened surface interface between a photovoltaic active layer and a transparent conductive oxide layer. The photovoltaic cell 200a includes a substrate layer 203a, a metal reflector layer 219a, and a photovoltaic active layer 211a disposed between the reflector layer 219a and the substrate layer 203a. The photovoltaic cell 200a also includes a first transparent conductive oxide layer 207a disposed between the substrate layer 203a and the photovoltaic active layer 211a, and a second transparent conductive oxide layer 215a disposed between the photovoltaic active layer 211a and the reflector layer 219a. In this way, the photovoltaic cell 200a includes a first surface interface 201a between an exposed surface of the substrate layer 203a and the environment, a second surface interface 205a between the substrate layer 203a and the first transparent conductive oxide layer 207a, a third surface interface 209a between the first transparent conductive oxide layer 207a and the photovoltaic active layer 211a, a fourth surface interface between the photovoltaic active layer 211a and the second transparent conductive oxide layer 215a, and a fifth surface interface between the second transparent conductive oxide layer 215a and the reflector layer 219a.

The materials and/or thickness dimensions of the layers of photovoltaic cell 200a can vary from implementation to implementation. In some implementations, the substrate layer 203a can include glass and/or plastic and have a thickness dimension of between about 0.5 mm and about 5 mm. The first transparent conductive oxide layer 207a can include any transparent conducting oxide (TCO), for example, aluminum-doped zinc oxide (ZnO:Al), fluorine-doped tin Oxide (SnO₂:F), and/or indium tin oxide (ITO), and can have a thickness dimension of between about 100 nm and about 1000 nm. The photovoltaic active layer 211a can include any suitable photovoltaic active material including microcrystalline silicon (μc-silicon), amorphous silicon (a-silicon), cadmium telluride (CdTe), copper indium diselenide (CIS), or copper indium gallium diselenide (CIGS), and can have a thickness dimension of between about 100 nm and about 5000 nm. The second transparent conductive oxide layer 215a can include any transparent conducting oxide (TCO), for example, aluminum-doped zinc oxide (ZnO:Al), fluorine-doped tin Oxide (SnO₂:F), and/or indium tin oxide (ITO), and can have a thickness dimension of between about 100 nm and about 2000 nm. The reflector layer 219a can include any reflective materials, for example, aluminum, and can have a thickness dimension of between about 100 nm and about 1000 nm.

As discussed in further detail below, the substrate layer 203a and the first transparent conductive oxide layer 207a can form a substrate stack 250a. The substrate stack 250a can be manufactured by one party and provided to another party that desires to manufacture the photovoltaic cell 200a. In some cases, a substrate stack 250a can constitute between about 10% and about 30% of the total cost of the photovoltaic cell 200a. Thus, methods that reduce the costs of manufacturing a substrate stack may also significantly reduce the overall cost of a photovoltaic cell that incorporates the substrate stack.

With continued reference to FIG. 2A, the substrate stack 250a may be manufactured by providing a polished substrate layer 203a and depositing a layer of transparent conductive oxide 207a thereon using chemical vapor deposition techniques. The layer of transparent conductive oxide 207a can include large crystals that can be exposed to one or more preferential chemical etches to roughen a surface of the transparent conductive oxide layer 207a opposite the substrate layer 203a. In this way, the surface of the transparent conductive oxide layer 207a that is opposite the substrate layer 203a can be roughened such that a surface interface 205a between the transparent conductive oxide layer 207a and a subsequently deposited photovoltaic active layer 211a is also rough. However, methods that include exposing transparent conductive oxide crystal facets to one or more preferential chemical etches are highly proprietary and costly for large area substrates. For these reasons, relatively few entities world-wide produce substrate stacks 250a including a roughened transparent conductive oxide surface that are suitable for high-volume panel production, which in turn inflates the costs of such stacks.

As mentioned above, roughened surface interfaces in a photovoltaic device can act to scatter light that passes therethrough and increase the light absorbing path of the scattered light beams through the subsequent layers of the photovoltaic device. The concept of scattering light that passes through a roughened surface interface is schematically illustrated in FIG. 2A with light beam 221a incident on the substrate layer 203a, passing through the front surface 201a, refracting within the substrate layer 203a, passing through the non-roughened surface interface 205a between the substrate layer 203a and the first transparent conductive oxide layer 207a into the first transparent conductive oxide layer, refracting within the first transparent conductive oxide layer, and scattering at the roughened surface interface 209a between the first transparent conductive oxide layer 207a and the photovoltaic active layer 211a. As schematically illustrated, the scattered light beams 225a are scattered within the photovoltaic active layer 211a such that their paths through the photovoltaic active layer are increased. The increase in the light absorbing paths of the scattered light beams 225a can increase the electrical power output by the photovoltaic cell 200a and/or can reduce the material requirement for the photovoltaic active layer 211a.

Turning now to FIG. 2B, an example of a cross-section of an implementation of a photovoltaic cell including a first roughened surface interface between a photovoltaic active layer and a transparent conductive oxide layer and a second roughened surface interface between the transparent conductive oxide layer and a substrate layer is schematically illustrated. The photovoltaic cell 200b includes a substrate layer 203b, a metal reflector layer 219b, and a photovoltaic active layer 211b disposed between the reflector layer 219b and the substrate layer 203b. The photovoltaic cell 200b also includes a first transparent conductive oxide layer 207b disposed between the substrate layer 203b and the photovoltaic active layer 211b, and a second transparent conductive oxide layer 215b disposed between the photovoltaic active layer 211b and the reflector layer 219b. In this way, the photovoltaic cell 200b includes a first surface interface 201b between an exposed surface of the substrate layer 203b and the environment, a second surface interface 205b between the substrate layer 203b and the first transparent conductive oxide layer 207b, a third surface interface 209b between the first transparent conductive oxide layer 207b and the photovoltaic active layer 211b, a fourth surface interface between the photovoltaic active layer 211b and the second transparent conductive oxide layer 215b, and a fifth surface interface between the second transparent conductive oxide layer 215b and the reflector layer 219b.

In contrast to the photovoltaic cell 200a of FIG. 2A, photovoltaic cell 200b in FIG. 2B includes two roughened surface interfaces at the entrance of light 221b. The second surface interface 205b can be roughened and the third surface interface 209b can also be roughened. As discussed in more detail below, substrate stack 250b can be manufactured by providing an un-polished substrate layer 203b, treating a surface of the substrate layer 203b to increase a surface roughness value of the substrate layer 203b, and depositing the first transparent conductive oxide layer 207b on the roughened surface of the substrate layer 203b. Because the surface roughness of the first transparent conductive oxide layer 207b (e.g., surface interfaces 205b, 209b) is a result of depositing the transparent conductive oxide material on a roughened substrate 203b, and do not require complicated preferential etching processes, the manufacturing cost of substrate stack 250b can be significantly less than the manufacturing cost of substrate stack 250a discussed with reference to FIG. 2A.

Still referring to FIG. 2B, the roughened surface interfaces 205b, 209b can each act to scatter light that passes therethrough. This scattering can increase the light absorbing path of the scattered light beams through the subsequent layers of the photovoltaic cell 200b. This concept of scattering light is schematically illustrated in FIG. 2B with light beam 221b incident on the substrate layer 203b, passing through the front surface 201b, refracting within the substrate layer 203b, and scattering at the second surface interface 205b into scattered light beams 223b. The scattered light beams 223b may travel through the first transparent conductive oxide layer 207b toward the photovoltaic active layer 211b and scatter at the third roughened surface interface 209b into more scattered light beams 225b. As schematically illustrated, many of the scattered light beams 225b propagate within the photovoltaic active layer 211b along paths that are a longer distance through the photovoltaic active layer 211b (e.g., longer than a more direct path perpendicular or near perpendicular to the photovoltaic active layer 211b), such that the path lengths of the light beams through the photovoltaic active layer are increased. This increase in the length of the light absorbing paths can increase the electrical power output by the photovoltaic cell 200b and/or can reduce the material requirement for the photovoltaic active layer 211b.

The surface roughness values of the second and third surface interfaces 205b, 209b can vary depending on the type of photovoltaic active layer 211b and/or the desired amount of light scattering. In one implementation, the photovoltaic active layer 211b may include amorphous silicon and the RMS roughness values of the second and third surface interfaces 205b, 209b can range between about 20 nm and about 200 nm. In another implementation, the photovoltaic active layer 211b may include microcrystalline silicon and the RMS roughness values of the second and third surface interfaces 205b, 209b can range between about 50 nm and about 500 nm. In one implementation, the photovoltaic active layer 211b may include copper indium gallium diselenide and the RMS roughness values of the second and third surface interfaces 205b, 209b can range between about 100 nm and about 1000 nm. In some implementations, the RMS roughness values of the second and/or third surface interfaces 205b, 209b can be greater than about 9 nm.

In some implementations, the second surface interface 205b and the third surface interface 209b can have the same RMS roughness value. In other implementations, the second surface interface 205b can have an RMS roughness value that is different than an RMS roughness value of the third surface interface 209b. For example, the third surface interface 209b can have an RMS roughness value that is greater than an RMS roughness value of the second surface interface 205b.

FIG. 2C is an example of a cross-section of one implementation of a photovoltaic cell including a first roughened surface interface between a photovoltaic active layer and a transparent conductive oxide layer and a second roughened surface interface between the transparent conductive oxide layer and a substrate layer. The photovoltaic cell 200c includes a substrate layer 203c, a metal reflector layer 219c, and a photovoltaic active layer 211c disposed between the reflector layer 219c and the substrate layer 203c. The photovoltaic cell 200c also includes a first transparent conductive oxide layer 207c disposed between the substrate layer 203c and the photovoltaic active layer 211c, and a second transparent conductive oxide layer 215c disposed between the photovoltaic active layer 211c and the reflector layer 219c. In this way, the photovoltaic cell 200c includes a first surface interface 201c between an exposed surface of the substrate layer 203c and the environment, a second surface interface 205c between the substrate layer 203c and the first transparent conductive oxide layer 207c, a third surface interface 209c between the first transparent conductive oxide layer 207c and the photovoltaic active layer 211c, a fourth surface interface 213c between the photovoltaic active layer 211c and the second transparent conductive oxide layer 215c, and a fifth surface interface 217c between the second transparent conductive oxide layer 215c and the reflector layer 219c.

In contrast to the photovoltaic cell 200b of FIG. 2B, the third surface interface 209c in FIG. 2C is schematically illustrated as having an RMS roughness value that is greater than an RMS roughness value of the second surface interface 205d. As discussed in further detail below, the surface roughness of the surface of the first transparent conductive oxide 207c opposite the substrate layer 203c can be optionally increased after the first transparent conductive oxide 207c is deposited by mechanically and/or chemically treating the surface. For example, the first transparent conductive oxide layer 207c can optionally be sand-blasted and/or chemically etched after the first transparent conductive oxide layer is conformally deposited on the roughened surface of the substrate layer 203c. In one implementation, the RMS roughness value of the second surface interface 205d can be about 10 nm and the RMS roughness value of the third surface interface 209c can be greater than about 10 nm, for example, between about 10 nm and about 500 nm.

Similar to the roughened surface interfaces discussed above with reference to FIG. 2B, the roughened surface interfaces 205c, 209c of photovoltaic cell 200c can each act to scatter light that passes therethrough. This scattering can increase the light absorbing path of the scattered light beams through the subsequent layers of the photovoltaic cell 200c. This concept of scattering light is schematically illustrated in FIG. 2C with light beam 221c incident on the substrate layer 203c, passing through the front surface 201c, refracting within the substrate layer 203c, and scattering at the second surface interface 205c into scattered light beams 223c. The scattered light beams 223c may travel through the first transparent conductive oxide layer 207c toward the photovoltaic active layer 211c and scatter at the third surface interface 209c into more scattered light beams 225c. As schematically illustrated, the scattered light beams 225c are scattered within the photovoltaic active layer 211c such that their paths through the photovoltaic active layer are increased. This increase in light absorbing paths can increase the electrical power output by the photovoltaic cell 200c and/or can reduce the material requirement for the photovoltaic active layer 211c.

FIG. 2D is an example of a cross-section of one implementation of a photovoltaic cell including a first roughened surface interface between a photovoltaic active layer and a transparent conductive oxide layer, a second roughened surface interface between the transparent conductive oxide layer and a substrate layer, and a third roughened surface interface on a side of the substrate layer opposite to the second roughened surface interface. The photovoltaic cell 200d includes a substrate layer 203d, a metal reflector layer 219d, and a photovoltaic active layer 211d disposed between the reflector layer 219d and the substrate layer 203d. The photovoltaic cell 200d also includes a first transparent conductive oxide layer 207d disposed between the substrate layer 203d and the photovoltaic active layer 211d, and a second transparent conductive oxide layer 215d disposed between the photovoltaic active layer 211d and the reflector layer 219d. In this way, the photovoltaic cell 200d includes a first surface interface 201d between an exposed surface of the substrate layer 203d and the environment, a second surface interface 205d between the substrate layer 203d and the first transparent conductive oxide layer 207d, a third surface interface 209d between the first transparent conductive oxide layer 207d and the photovoltaic active layer 211d, a fourth surface interface between the photovoltaic active layer 211d and the second transparent conductive oxide layer 215d, and a fifth surface interface between the second transparent conductive oxide layer 215d and the reflector layer 219d.

In contrast to the photovoltaic cells 200 of FIGS. 2A and 2B, in the implementation schematically illustrated in FIG. 2D, the first surface interface 201d is a roughened surface interface. In some implementations, the exposed surface of the substrate layer 203d at the first surface interface can be generally smooth and have an RMS roughness value of about 1 nm or less. However, as shown in FIG. 2D, the roughness of the exposed surface can optionally be increased to promote additional light scattering at the first surface interface 201d. The surface roughness value of the first surface interface 201d can be less than, greater than, or about the same, as a surface roughness of the second surface interface 205d and/or of the third surface interface 209d. In one implementation, first surface interface 201d can have an RMS roughness value of greater than about 1 nm, for example, greater than about 4 nm.

Similar to the roughened surface interfaces discussed above with reference to FIGS. 2A-2C, the roughened first surface interface 201d of photovoltaic cell 200d is configured to scatter light that passes therethrough. This scattering can increase the light absorbing path of the scattered light beams through the subsequent layers of the photovoltaic cell 200d, including the photovoltaic active layer 211d. This concept of scattering light is schematically illustrated in FIG. 2D with light beam 220d incident on the substrate layer 203d scattering at the first surface interface 201d into scattered light beams 221d. These scattered light beams pass through the substrate layer 203d and are scattered at the second surface interface 205d into additional scattered light beams 223d. These scattered light beams 223d pass through the first transparent conductive oxide layer 207d to the third surface interface 209d where they are further scattered into scattered light beams 225d. Light beams 225d are scattered within the photovoltaic active layer 211d by the surface features of the roughened third surface interface such that the length of their propagation paths through the photovoltaic active layer 211d are increased. This increase in light absorbing paths can increase the electrical power output by the photovoltaic cell 200d and/or can reduce the material requirement for the photovoltaic active layer 211d.

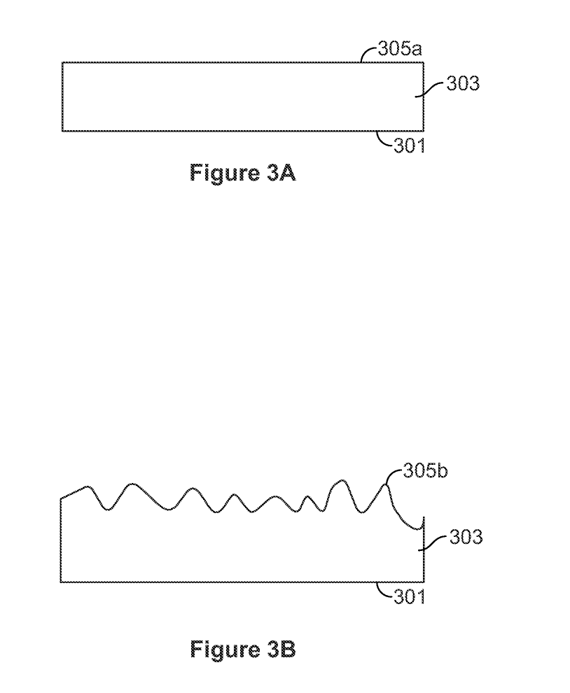

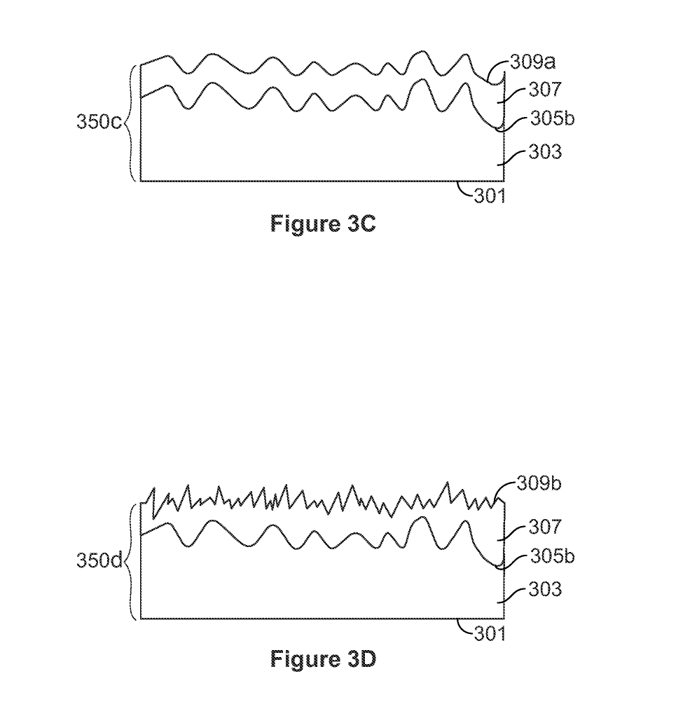

FIG. 3A is an example of a cross-section of one implementation of a substrate layer used to manufacture a substrate stack. The substrate layer 303 can include any at least partially transparent material, for example, glass and/or plastic. The substrate layer 303 includes a first surface 301 that may be configured to receive light therethrough such that the light passes into the substrate layer 303. The substrate layer 303 may further include a second surface 305a disposed opposite to the first surface 301. In contrast to many existing methods of manufacturing photovoltaic cells and/or substrate stacks for use in photovoltaic cells, the substrate layer 303 may be used to manufacture a substrate stack without polishing the first surface 301 and/or the second surface 305a. This can reduce the costs and times required to manufacture substrate stacks and/or photovoltaic cells.

FIG. 3B is an example of a cross-section of the substrate layer of FIG. 3A after one surface of the substrate layer has been roughened. As schematically illustrated in FIG. 3B, the second surface 305a of the substrate layer 303 can be processed to increase the surface roughness resulting in a roughened second surface 305b. The second surface 305a can be roughened using mechanical and/or chemical processes. For example, the second surface 305a may be roughened by sand-blasting and/or chemically etching the substrate layer 303. Although not illustrated in FIG. 3B, the first surface 301 may also optionally be roughened to create a roughened first surface interface as discussed above with reference to FIG. 2D.

FIG. 3C is an example of a cross-section of the substrate layer of FIG. 3B shown with a transparent conductive oxide layer deposited on the roughened surface. The transparent conductive oxide layer 307 and the substrate layer 303 form a substrate stack 350c. The transparent conductive oxide layer 307 can be conformally deposited using chemical vapor deposition techniques such that a surface of the transparent conductive oxide layer 307 in contact with the substrate layer 303 matches the second surface 305b and such that a surface 309a of the transparent conductive oxide layer 307 opposite to the substrate layer 309a also matches the second surface 305b. Thus, the surface roughness values of the second surface 305b and of surface 309a of the transparent conductive oxide layer 307 can be about the same, for example, greater than about 9 nm.

FIG. 3D is an example of a cross-section of the substrate layer and transparent conductive oxide layer of FIG. 3C after a surface of the transparent conductive oxide layer opposite the substrate layer has been roughened. In some implementations, the surface 309b is roughened by sand-blasting and/or chemically etching the transparent conductive oxide layer 303 to enhance the scattering of light that passes therethrough. Substrate stacks 350c, 350d of FIGS. 3C and 3D can be used to manufacture a photovoltaic cell by subsequently depositing a photovoltaic active layer over the roughened surfaces 309a, 309b.

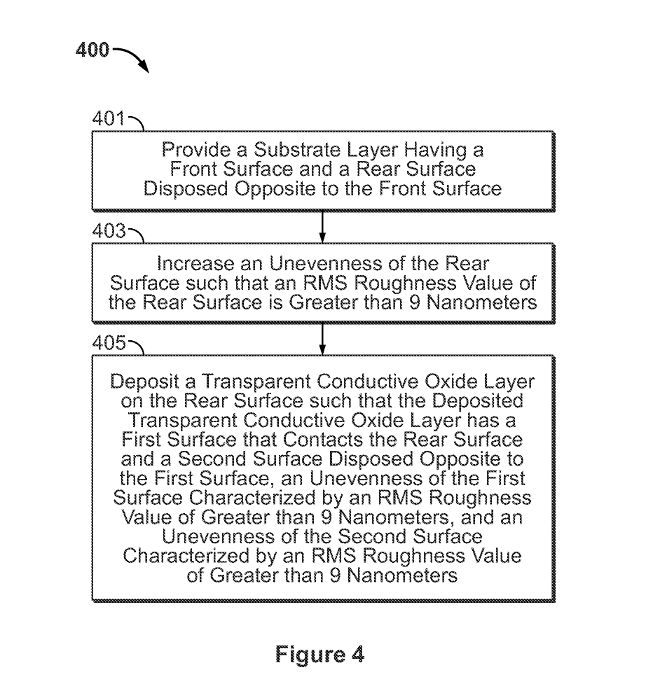

FIG. 4 is an example of a block diagram schematically illustrating one implementation of a method of manufacturing a substrate stack for use in a photovoltaic cell. As illustrated in block 401, method 400 includes providing a substrate layer having a front surface and a rear surface disposed opposite to the front surface. In some implementations, the substrate layer can be similar to the substrate layers 203 of FIGS. 2A-2D and/or the substrate layers 303 of FIGS. 3A-3D. The substrates provided can be pre-polished and/or un-polished. Method 400 further includes increasing an unevenness of the rear surface such that an RMS roughness value of the rear surface is greater than 9 nm as illustrated in block 403. The unevenness of the rear surface can be increased by mechanically and/or chemically treating the rear surface. For example, the rear surface can be sand-blasted and/or chemically etched to increase the unevenness such that an RMS roughness value of the rear surface is greater than 9 nm.

As shown in block 405, the method 400 can also include depositing a transparent conductive oxide layer on the rear surface such that the deposited transparent conductive oxide layer has a first surface that contacts the rear surface and a second surface disposed opposite to the first surface. In this way, an unevenness of the first surface can be characterized by an RMS roughness value of greater than 9 nm and an unevenness of the second surface can be characterized by an RMS roughness value of greater than 9 nm. The transparent conductive oxide layer can be deposited conformally such that the first surface has an RMS roughness value that is about the same as the second surface. Also, the second surface can be further treated or processed such that the unevenness of the second surface is greater than the unevenness of the first surface.

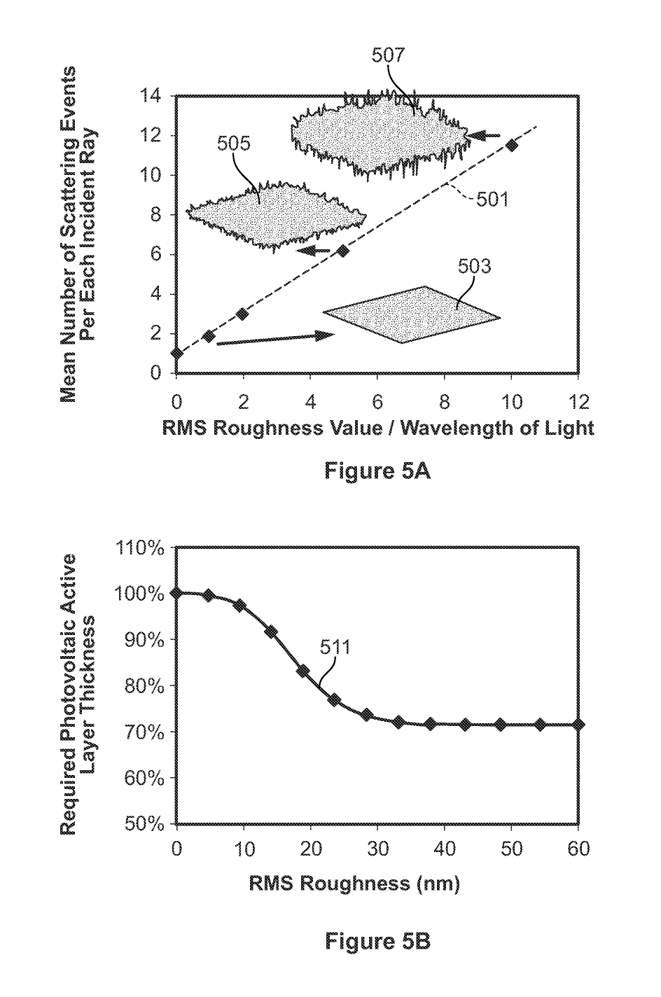

FIG. 5A is an example of a chart that relates the light scattering to the surface roughness of a light surface interface. As discussed above, the surface roughness of a surface interface may promote the scattering of light that passes through the surface interface. This concept is schematically illustrated in FIG. 5A which includes an example of a chart relating the mean number of scattering events per each incident ray of light to a quotient of the surface interface RMS roughness value and the wavelength of the incident rays of light. The chart includes schematic representations 503, 505, 507 of different surface roughness values. A first schematic representation 503 is relatively even to illustrate a surface having a relatively low RMS roughness value. A second representation 505 is rougher than the first representation 505 to illustrate a surface having an RMS roughness value that is relatively higher than the RMS roughness value of the first representation 503. A third representation 507 is rougher than the second representation 503 to illustrate a surface having an RMS roughness value that is relatively higher than the RMS roughness value of the second representation 505. The broken line 501 on the chart shows that the mean number of scattering events per each incident ray of light increases as the RMS roughness value of the surfaces increase. Accordingly, larger RMS roughness values lead to more scattering events.

As discussed above, light scattering can increase the light absorbing path of the scattered light which can reduce the required thickness for the photovoltaic active layer. FIG. 5B is an example of a chart that relates the thickness requirement for a photovoltaic active layer to the surface roughness of a front transparent conductive oxide layer of a photovoltaic cell. The chart includes a curve 511 that relates the increase in RMS roughness to the decrease in photovoltaic active layer thickness (as a percentage of the thickness when the RMS roughness value is approximately 0 nm). One having ordinary skill in the art will appreciate that the thickness required for a photovoltaic active layer to output a certain electrical power can be decreased by more than 20% if the RMS roughness value of a surface interface of a front transparent conductive oxide layer is increased to about 20 nm or more. It follows that reducing the required thickness for a photovoltaic active layer can reduce material costs and fabrication time (e.g., time required to deposit the photovoltaic active layer) for a photovoltaic cell.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the photovoltaic cell as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A substrate stack for use in a photovoltaic cell, the substrate stack comprising:
a substrate layer having a front surface and a rear surface disposed opposite to the front surface, wherein an unevenness of the rear surface is characterized by an RMS roughness value that is greater than 9 nanometers; and
a first transparent conductive oxide layer disposed over the rear surface of the substrate layer, the first transparent conductive oxide layer having a first surface disposed adjacent to the rear surface of the substrate layer, and having a second surface disposed opposite to the first surface, wherein an unevenness of the first surface is characterized by an RMS roughness value of greater than 9 nanometers, and wherein an unevenness of the second surface is characterized by an RMS roughness value of greater than 9 nanometers.

2. The substrate stack of claim 1, further comprising a photovoltaic active layer disposed over the second surface of the first transparent conductive oxide layer.

3. The substrate stack of claim 2, wherein the photovoltaic active layer contacts the second surface of the first transparent conductive oxide layer.

4. The substrate stack of claim 3, wherein the photovoltaic active layer is configured to produce a current flow when the photovoltaic layer receives electromagnetic radiation through the front surface of the substrate layer.

5. The substrate stack of claim 2, further comprising a second transparent conductive oxide layer disposed over the photovoltaic active layer, such that the photovoltaic active layer is between the first transparent conductive oxide layer and the second transparent conductive oxide layer.

6. The substrate stack of claim 5, further comprising a reflective layer disposed over the second transparent conductive oxide layer such that the second transparent conductive oxide layer is disposed between the reflective layer and the photovoltaic active layer.

7. The substrate stack of claim 2, wherein the photovoltaic active layer has a thickness dimension characteristic of between 100 and 5000 nanometers.

8. The substrate stack of claim 1, wherein the RMS roughness value of the unevenness of the first surface of the first transparent conductive oxide layer is between 10 nanometers and 200 nanometers.

9. The substrate stack of claim 8, wherein the RMS roughness value of the unevenness of the first surface of the first transparent conductive oxide layer is about the same as the RMS roughness value of the unevenness of the rear surface of the substrate layer.

10. The substrate stack of claim 8, wherein the RMS roughness value of the unevenness of the second surface of the first transparent conductive oxide layer is between 20 nanometers and 1000 nanometers.

11. The substrate stack of claim 10, wherein the photovoltaic active layer comprises at least one of copper, indium, gallium, and selenium.

12. The substrate stack of claim 11, wherein the RMS roughness value of the unevenness of the second surface of the first transparent conductive oxide layer is between 100 and 1000 nanometers.

13. The substrate stack of claim 10, wherein the photovoltaic active layer comprises amorphous silicon.

14. The substrate stack of claim 13, wherein the RMS roughness value of the unevenness of the second surface of the first transparent conductive oxide layer is between 20 and 200 nanometers.

15. The substrate stack of claim 10, wherein the photovoltaic active layer comprises microcrystalline silicon.

16. The substrate stack of claim 15, wherein the RMS roughness value of the unevenness of the second surface of the first transparent conductive oxide layer is between 50 and 500 nanometers.

17. The substrate stack of claim 10, wherein the RMS roughness value of the unevenness of the second surface of the first transparent conductive oxide layer is greater than the RMS roughness value of the unevenness of the first surface of the first transparent conductive oxide layer.

18. The substrate stack of claim 1, wherein an RMS roughness value of an unevenness of the front surface of the substrate layer is greater than about 1 nanometer.

19. The substrate stack of claim 18, wherein the RMS roughness value of the unevenness of the front surface of the substrate layer is greater than 4 nanometers.

20. The substrate stack of claim 1, wherein the substrate layer has a thickness dimension characteristic of between 0.5 and 5 millimeters.

21. The substrate stack of claim 1, wherein the first transparent conductive oxide layer has a thickness dimension characteristic of between 100 and 500 nanometers.

22. The substrate stack of claim 1, wherein the substrate layer comprises glass.

23. The substrate stack of claim 1, wherein the first transparent conductive oxide layer comprises at least one of aluminum-doped zinc oxide, fluorine-doped tin oxide, and indium-tin oxide.

24. A substrate stack for use in a photovoltaic cell, the substrate stack comprising:
a substrate layer having a front surface and a rear surface disposed opposite to the front surface; and
a first transparent conductive oxide layer disposed over the rear surface of the substrate layer, the first transparent conductive oxide layer including a first surface and a second surface, the first surface disposed between the second surface and the rear surface of the substrate layer, the first surface having an unevenness characterized by an RMS roughness value of greater than 9 nanometers and the second surface having an unevenness characterized by an RMS roughness value that is greater than the RMS roughness value of the unevenness of the first surface.

25. The substrate stack of claim 24, wherein an unevenness of the rear surface of the substrate layer is characterized by an RMS roughness value greater than 19 nanometers.

26. The substrate stack of claim 25, wherein the unevenness of the second surface of the first transparent conductive oxide layer is characterized by an RMS roughness value of between 20 and 1000 nanometers.

27. The substrate stack of claim 24, further comprising a photovoltaic active layer disposed over the second surface of the first transparent conductive oxide layer.

28. The substrate stack of claim 27, wherein the photovoltaic active layer contacts the second surface of the first transparent conductive oxide layer.

29. The substrate stack of claim 28, wherein the photovoltaic active layer is configured to produce a current flow when the photovoltaic layer receives electromagnetic radiation, especially sun light, through the front surface of the substrate layer.

30. The substrate stack of claim 27, further comprising a second transparent conductive oxide layer disposed over the photovoltaic active layer, such that the photovoltaic active layer is between the first transparent conductive oxide layer and the second transparent conductive oxide layer.

31. The substrate stack of claim 27, wherein the photovoltaic active layer comprises copper, indium, gallium, and selenium.

32. The substrate stack of claim 31, wherein the RMS roughness value of the unevenness of the second surface of the first transparent conductive oxide layer is between 100 and 1000 nanometers.

33. The substrate stack of claim 27, wherein the photovoltaic active layer comprises amorphous silicon.

34. The substrate stack of claim 33, wherein the RMS roughness value of the unevenness of the second surface of the first transparent conductive oxide layer is between 20 and 200 nanometers.

35. The substrate stack of claim 27, wherein the photovoltaic active layer comprises microcrystalline silicon.

36. The substrate stack of claim 35, wherein the RMS roughness value of the unevenness of the second surface of the first transparent conductive oxide layer is between 50 and 500 nanometers.

37. A method of manufacturing a substrate stack for use in a photovoltaic cell, the method comprising:
providing a substrate layer having a front surface and a rear surface disposed opposite to the front surface;
increasing an unevenness of the rear surface such that an RMS roughness value of the rear surface is greater than 9 nanometers; and
depositing a transparent conductive oxide layer on the rear surface such that the deposited transparent conductive oxide layer has a first surface that contacts the rear surface and a second surface disposed opposite to the first surface, an unevenness of the first surface characterized by an RMS roughness value of greater than 9 nanometers, and an unevenness of the second surface characterized by an RMS roughness value of greater than 9 nanometers.

38. The method of claim 37, further comprising increasing the unevenness of the second surface such that the RMS roughness value of the unevenness of the second surface is greater than the RMS roughness value of the first surface.

39. The method of claim 37, further comprising depositing a photovoltaic active layer on the second surface such that the photovoltaic active layer is configured to receive electromagnetic radiation through the substrate layer and the first transparent conductive oxide layer.

40. The method of claim 37, wherein increasing the unevenness of the rear surface comprises mechanically treating the substrate layer.

41. The method of claim 40, wherein increasing the unevenness of the rear surface comprises sandblasting the substrate layer.

42. The method of claim 37, wherein increasing the roughness of the rear surface comprises chemically treating the substrate layer.

43. The method of claim 42, wherein increasing the roughness of the rear surface comprises etching the substrate layer.

44. The method of claim 37, wherein the transparent conductive oxide layer is deposited on the rear surface by chemical vapor deposition such that the RMS roughness value of the unevenness of the second surface is greater than the RMS roughness value of the unevenness of the first surface.

45. The method of claim 37, further comprising increasing the roughness of the second surface such that the RMS roughness value of the unevenness of the second surface is greater than the RMS roughness value of the unevenness of the first surface.

46. A substrate stack for use in a photovoltaic cell, the substrate stack comprising:
a substrate layer having a front surface and a rear surface disposed opposite to the front surface; and
means for conducting a current flow, the conductive means disposed over the rear surface of the substrate layer and having a first surface and a second surface disposed opposite to the first surface, wherein the first surface is disposed between the second surface and the rear surface of the substrate layer,
wherein an unevenness of the first surface is characterized by an RMS roughness value of greater 9 nanometers, and wherein an unevenness of the second surface is characterized by an RMS roughness value that is greater than the RMS roughness value of the first surface.

47. The substrate stack of claim 46, wherein the conductive means comprises a transparent conductive oxide layer.

48. The substrate stack of claim 46, wherein the RMS roughness value of the unevenness of the second surface is between 20 and 1000 nanometers.
